(19) United States
(12) Patent Application Publication
(10) Pub. No.: US 2024/0334841 A1
(43) Pub. Date: Oct. 3, 2024

(54) LOW-STRESS NBN SUPERCONDUCTING THIN FILM AND PREPARATION METHOD AND APPLICATION THEREOF

(71) Applicant: ZHEJIANG LAB, Hangzhou (CN)

(72) Inventors: LIHUI YANG, HANGZHOU (CN); XIAOHANG ZHANG, HANGZHOU (CN); CHAO ZHANG, HANGZHOU (CN); RAN DUAN, HANGZHOU (CN); ZHIFENG ZHAO, HANGZHOU (CN); DI LI, HANGZHOU (CN); SHILING YU, HANGZHOU (CN); YI FENG, HANGZHOU (CN)

(21) Appl. No.: 18/375,509

(22) Filed: Sep. 30, 2023

(30) Foreign Application Priority Data
Apr. 3, 2023 (CN) 202310369719.1

(51) Int. Cl. H10N 60/01; C23C 14/06; C23C 14/35; G01J 5/20

(52) U.S. Cl. CPC H10N 60/0241; C23C 14/0641; C23C 14/35; G01J 5/20; G01J 2005/208

(57) ABSTRACT

The present invention discloses the low-stress niobium nitride (NbN) superconducting thin film and preparation method and application thereof. The preparation method includes the following steps: providing the metal Nb target and the Si-based substrates, fixing the Si-based substrate at room temperature, adjusting the mass flow ratio of N₂/Ar to 20%-50%, the sputtering power to 50-400 W and the deposition pressure to 3.0-10.0 mTorr, NbN superconducting thin films with a stress range of-500 MPa˜500 MPa and a thickness of 70-150 nm were deposited on Si-based substrates. By synergistically controlling the mass flow rate ratio of N₂/Ar, sputtering power, and deposition pressure, low stress NbN superconducting thin films can be easily and efficiently prepared. The stress range of the prepared NbN superconducting thin films meets the preparation requirements of superconducting dynamic inductance detectors, and can be mass-produced.

### TECHNICAL FIELD

The present invention belongs to the technical field of superconducting niobium nitride thin films, more particularly relates to the low-stress NbN superconducting thin film and preparation method and application thereof.

### BACKGROUND TECHNOLOGY

Niobium nitride (NbN) superconducting thin film has a relatively high superconducting transition temperature (Tc˜17 K). Compared with superconducting silicide such as MoSi and WSi with an operating temperature of about 2 K, the operating temperature of superconducting devices based on-NbN thin film can be achieved in a low-cost 4.2 K liquid helium cryocooler. In addition, the NbN thin film also has high dynamic inductance, narrow transition width, small superconducting energy gap (Δ(0)-2.5 meV), good material stability, relatively simple preparation process, and meanwhile, has an operating frequency of 1,400 GHZ, falling in a terahertz band. Therefore, it has been widely used in various superconducting electronic devices, such as terahertz superconducting dynamic inductance thermal detectors, superconducting electronic devices based on a superconducting Josephson junction, and superconducting nanowire single photon detectors.

The stress of NbN superconducting thin film is directly associated with the yield, stability and reliability of the superconducting electronic devices. In recent years, effects of the stress of materials have become an important field of physics research on device reliability in the world, and reports of device failure caused by the stress have also been found in China. During the growth process thin films, factors such as defect areas (grain boundary, dislocation, vacancy, impurity, etc), interface areas (film and substrate, film and vacuum), and dynamic processes (recrystallization and diffusion) in the film lead to the generation of internal stress. The internal stress directly affects the quality, crystal structure and superconductivity of the thin film, and excessive internal stress will cause thin films and substrates to crack into fragments, making them unsuitable for application.

Currently, NbN thin films are typically grown using high vacuum magnetron sputtering technology and usually require substrate temperature ranging from of 450° C. to 850° C. On one hand, the high deposition temperature limits the preparation process of superconducting detectors, making them incompatible with subsequent device processes such as lift-off; On the other hand, the high deposition temperature and rapid growth of crystal nuclei actually affect the density of the thin film. Moreover, during the process of falling from high temperature to room temperature after deposition, additional thermal stress will be introduced due to the difference in thermal expansion coefficient between the film and substrate. Residual stress in the thin film is difficult to control, which is usually exceeding 1000 MPa or even 1 GPa, which can affect the stability and reliability of superconducting detectors and even cause device failure.

The existing NbN thin films are generally prepared by selecting single crystal substrates, such as MgO with small lattice mismatch, or by using GaN, TiN or Nb₅N₆ buffer layers on high-resistance Si substrates. The process is complex and costly, for example, MgO substrates are expensive, the micro/nano processing technology for subsequent devices is not mature, and the device operates at high frequencies with high losses. In order to meet development needs of terahertz superconducting dynamic inductance thermal detectors, it is of great significance to propose a room temperature growth method for low-stress NbN superconducting thin film on Si-based substrates.

### SUMMARY OF THE INVENTION

In view of the above situations, the object of the present invention is to provide the low-stress NbN superconducting thin film and preparation method and application thereof, so as to realize a simple preparation method of a low-stress NbN superconducting thin film.

In order to realize the object of the present invention, an embodiment provides a preparation method of low-stress NbN superconducting thin film. The method includes the following steps:

providing metal Nb targets and Si-based substrates, fixing the Si-based substrate at room temperature, by adjusting the N₂/Ar mass flow ratio to 5%-50%, the sputtering power to 50-800 W and the deposition pressure to 1.0-10.0 mTorr, NbN superconducting thin films with a stress range of-500 MPa˜500 MPa and a thickness of 70-150 nm are deposited on Si substrate.

During the reactive sputtering preparation process, the fixed temperature of Si-based substrate is room temperature, which avoids additional thermal stress caused by the different thermal expansion coefficients between the thin film and substrate during the process of falling from high temperature to room temperature after film deposition. By synergistically controlling the mass flow rate ratio of N₂ and Ar, the sputtering power and the deposition pressure, the rate and energy of sputtering ions reaching the Si-based substrate are regulated, thereby changing the phase formation mode and crystal nucleation mode during the growth process of the NbN superconducting thin film, effectively altering the defect areas, interface areas, and dynamic processes states-generated during crystal growth process. Finally, the regulation of the internal stress state and magnitude of NbN superconducting thin film is achieved. At room temperature, by controlling the mass flow ratio of N₂/Ar to be 5%-50%, the sputtering power to be 50-500 W and the deposition pressure to be 1.0-10.0 mTorr, the stress of the NbN thin film can be adjusted to −500 MPa˜500 MPa, which is within a low stress range with absolute values of less than 500 MPa, wherein a negative value indicates compressive stress, a positive value indicates tensile stress, and the density and surface roughness of NbN thin film remain basically unchanged.

The N₂/Ar mass flow ratio is 20%-40%, the sputtering power is 100-300 W, the deposition pressure is 3.0-10.0 mTorr, and the deposition is performed on the Si-based substrate to obtain the NbN superconducting thin film having a stress range of-300 MPa to 300 MPa and a thickness of 70-150 nm.

The N₂/Ar mass flow ratio is 20%-25%, the sputtering power is 150-300 W, the deposition pressure is 3.0-10.0 mTorr, and the deposition is performed on the Si-based substrate to obtain the NbN superconducting thin film having a stress range of-200 MPa to 200 MPa and a thickness of 50-150 nm.

The N₂/Ar mass flow ratio is 20%-25%, the sputtering power is 200-300 W, the deposition pressure is 3.0-8 mTorr, and the deposition is performed on the Si-based substrate to obtain the NbN superconducting thin film having a stress range of −100 MPa to 100 MPa and a thickness of 70-150 nm. Under same conditions, when thickness of the film is very thin, small islands forming the thin film are not connected to each other and even if they are connected, they still form a network structure, and internal stress is low at this time. As the film thickness increases, the small islands are connected to each other. Due to the difference in lattice arrangement between the small islands and the presence of small holes, the internal stress rapidly increases and a critical value appears. When the film thickness further increases and a continuous thin film is formed, no small holes are found in the film, and the stress decreases and tends to be a stable value.

The metal Nb target is a high-purity metal niobium target with a purity of 99.99%.

The Si-based substrate is the high-resistance Si substrate coated with the SiNₓ thin film.

After the metal Nb target and the Si-based substrate are placed into the film deposition chamber, which is required to be vacuumized to an ultrahigh vacuum, where the background vacuum degree of ultra-high vacuum is less than 5.0×10⁻⁸ Torr. In such ultrahigh vacuum the pollution of residual gas molecules such as oxygen, nitrogen, water and hydrocarbons can be reduced, and the involvement of residual gases in reactive sputtering of NbN thin film can be avoided. This is a prerequisite for obtaining homogeneous, stable, low stress, and high-quality NbN superconducting thin films.

The Si-based substrate is need to be cleaned before film deposition, the Si-based substrate is subjected to ion cleaning for 1-3 min to remove impurity ions from the substrate surface. The ion beam for ion cleaning is Argon ion beam, with an ion cleaning vacuum environment of less than 5.0×10⁻⁸ Torr, an argon flow rate of 20-100 sccm, an ion source power of 30-100 W and a working pressure of 1.0-10.0 mTorr, and an ion cleaning time controlled within 60-300 s.

Before NbN superconducting thin film deposition, pre-sputtering was also included. The pre-sputtering parameters are: the N₂/Ar mass flow ratio of 5%-50%, the sputtering power of 50-800 W, the deposition pressure of 1.0-10.0 mTorr, and the sputtering time of 60-300 s.

An embodiment further provides a low-stress NbN superconducting thin film, wherein the low-stress NbN superconducting thin film is prepared by the above preparation method and has a thickness of 70-150 nm.

An embodiment further provides an application of the low-stress NbN superconducting thin film in a terahertz superconducting dynamic inductance thermal detector, wherein the low-stress NbN superconducting thin film is prepared by the above preparation method. In a terahertz superconducting dynamic inductance thermal detector, the bending dynamic inductance of the low-stress NbN superconducting thin film is used as a temperature sensor.

Compared to the existing technologies, the beneficial effects of the present invention at least include:
Based on the magnetron sputtering, low stress NbN superconducting thin films can be easily and efficiently prepared by selecting Si-based substrates that are compatible with mature semiconductor processes, and controlling the mass flow ratio of N₂/Ar, sputtering power, and deposition pressure at room temperature. The stress range of the prepared NbN superconducting thin films meets the requirements of superconducting dynamic inductance detectors, and can be mass industrial produced.

### BRIEF DESCRIPTION OF DRAWINGS

In order to illustrate embodiments of the present invention or technical schemes in the prior art more clearly, accompanying drawings required to be used in the description of the embodiments or the prior art are briefly introduced below. Obviously, the drawings in the following description are only some embodiments of the present invention. For those of ordinary skill in the art, other drawings can also be obtained from these drawings without creative efforts.

FIG. 1 shows the XRD diffraction patterns of NbN superconducting thin films under the conditions of the N₂/Ar flow ratio of 20%, the deposition pressure of 3.1 mTorr and the sputtering power of 100, 150, 300, 400 and 500 W, respectively;

FIG. 2 shows the XRD diffraction patterns of NbN superconducting thin films under the conditions of the sputtering power of 300 W, the deposition pressure of 3.1 mTorr and the N₂/Ar flow ratio of 10%, 20%, 30%, 40% and 50%, respectively;

FIG. 3 shows the XRD diffraction patterns of NbN superconducting thin films under the conditions of the N₂/Ar flow ratio of 20%, the sputtering power of 300 W and the deposition pressure of 2.0, 3.1, 5 and 10 mTorr, respectively;

FIG. 4 shows the variation of the internal stress of NbN superconducting thin film with the N₂/Ar flow ratio under the conditions of sputtering power of 300 W and deposition pressure of 3.1 mTorr;

FIG. 5 shows the variation of the internal stress of NbN superconducting thin film with the sputtering power under the conditions of N₂/Ar flow ratio of 20% and deposition pressure of 3.1 mTorr;

FIG. 6 shows the variation of the internal stress of NbN superconducting thin film with the deposition pressure under the conditions of N₂/Ar flow ratio of 20% and sputtering power of 300 W.

### DETAILED DESCRIPTION OF EMBODIMENTS

In order to make the object, technical schemes and advantages of the present invention more clearly understood, the present invention is further described in detail below in combination with the accompanying drawings and embodiments. It is to be understood that the specific embodiments described herein are intended only to explain the present invention, rather than to limit the scope of protection of the present invention.

An embodiment provides a low-stress NbN superconducting thin film and preparation method and application thereof. The method includes the following steps.

### Step 1, Preparation and Treatment of the Target:

A metal Nb target with a purity of 99.99% is prepared and loaded into the chamber of the high-vacuum magnetron sputtering system. Insufficient vacuum may affect the movement of the plasma, leading to a decrease in controllability and repeatability of the thin film deposition process. Therefore, the background vacuum degree of the deposition chamber is need to be less than 5.0×10⁻⁸ Torr.

### Step 2, Selection and Treatment of the Substrate:

The high-resistance Si substrates coated with SiNₓ thin film are selected. The Si-based substrates are compatible with mature semiconductor process, and high-quality thin film growing on the Si-based substrates, which helps promote the preparation and application of materials in superconducting detector.

Regard the treatment of the Si substrates, ultrasonic cleaning is carried out using acetone, alcohol, and deionized water in order to remove oily impurities on the surface. Then the substrate is blow-dried with N₂ gun and loaded into the sample transmission chamber of the magnetron sputtering system and vacuum it. The substrate is transmitted into the deposition chamber of the magnetron sputtering system when the vacuum is less than 5.0×10⁻⁶ Torr. Before pre-sputtering, ion cleaning is carried out on the substrate for 1-3 min to remove impurity ions from the surface of the substrate, wherein an argon ion beam is used for the ion cleaning, the ion cleaning is performed in a vacuum environment under the vacuum degree of less than 5.0×10⁻⁸ Torr, the argon flow rate of 20-100 sccm, the ion source power of 30-100 W and the working pressure of 1.0-10.0 mTorr, and the ion cleaning time is controlled within 60-300 s.

### Step 3, Pre-Sputtering of NbN Thin Film:

The main reason for pre-sputtering is that the target is easily to attach impurities when stored outside, and many target surfaces are prone to oxidation after contact with air. It can easily lead to impure composition and poor quality of the thin film without pre-sputtering. A certain pre-sputtering time can ensure the purity of the target during sputtering. During the pre-sputtering, the mass flow ratio of the reaction gas N₂ to the working gas Ar is set to 5%-50% first, then the power source is turned on, and the sputtering power is set to 50-800 W, the working pressure is adjusted to 1.0-10.0 mTorr, and the power source is turned on for build-up of luminance. After successful ignition, a layer of glow on the surface of the target can be seen from the observation window. At this time, the working pressure can be lowered for pre-sputtering, with the sputtering time of 60-300 s.

### Step 4, Deposition of NbN Superconducting Thin Film:

After the pre-sputtering is completed, all impurities of in the oxide layer on the surface of the target are sputtered off, maintaining the purity of target surface. The Si-based substrate is fixed at room temperature. Then, the mass flow ratio of the reaction gas (N₂) to the working gas (Ar) is checked again and adjusted to be 5%-50%, the sputtering power is adjusted to be 50-800 W, the deposition pressure is adjusted to be 1.0-10.0 mTorr, and the sputtering time is set to be 300-1,800 s based on an expected sputtering rate. The baffle below the target is turned on for the formal NbN film deposition.

### Step 5, Sampling:

After the set sputtering time is reached, the sputtering ends. When the instrument timing is zero, the power source will be turned off, the baffle is closed, a gate valve is switched off automatically, then the substrate is transferred to the sample transmission chamber. An air inlet valve is switched on for ventilation until the pressure-is recovered to atmospheric pressure, then the chamber door is opened and the sample is taken out.

The NbN superconducting thin films are prepared in the following specific examples and comparative examples based on the above steps 1-5, as shown in Table 1 and Table 2.

TABLE 1

| | | Example | Example | Example | Example | Comparative | Comparative |
|---|---|---|---|---|---|---|---|
| | | 1 | 2 | 3 | 4 | Example 1 | Example 2 |
| Ion cleaning | Vacuum | 3.6 | 3.6 | 3.6 | 3.6 | 3.6 | 3.6 |
| parameter | degree | | | | | | |
| | (×10⁻⁸ Torr) | | | | | | |
| | Ar flow | 59 | 59 | 59 | 59 | 59 | 59 |
| | rate (sccm) | | | | | | |
| | Ion source | 50 | 50 | 50 | 50 | 50 | 50 |
| | power (W) | | | | | | |
| | Working | 10 | 10 | 10 | 10 | 10 | 10 |
| | pressure | | | | | | |
| | (mTorr) | | | | | | |
| | Time (s) | 180 | 180 | 180 | 180 | 180 | 180 |
| Pre-sputtering | Mass flow | 20% | 20% | 20% | 20% | 20% | 20% |
| Parameter | ratio | | | | | | |
| | (N₂:Ar) | | | | | | |
| | Sputtering | 300 | 300 | 300 | 300 | 300 | 300 |
| | power (W) | | | | | | |
| | Deposition | 10 | 10 | 10 | 10 | 10 | 10 |
| | pressure | | | | | | |
| | (mTorr) | | | | | | |
| | Sputtering | 180 | 180 | 180 | 180 | 180 | 180 |
| | time (s) | | | | | | |
| Sputtering | Mass flow | 20% | 20% | 20% | 20% | 20% | 10% |
| Parameter | ratio | | | | | | |
| | (N₂:Ar) | | | | | | |
| | Sputtering | 100 | 150 | 300 | 400 | 500 | 300 |
| | power (W) | | | | | | |
| | Deposition | 3.1 | 3.1 | 3.1 | 3.1 | 3.1 | 3.1 |
| | pressure | | | | | | |
| | (mTorr) | | | | | | |
| | Sputtering | 1620 | 1080 | 540 | 405 | 324 | 540 |
| | time (s) | | | | | | |
| Stress | (MPa) | −214 | −190.6 | 32 | 418 | 968 | 939.5 |
| Thickness | (nm) | 73 | 95 | 131 | 116 | 137 | 136 |

TABLE 2

| | | Example | Example | Example | Comparative | Example | Example |
|---|---|---|---|---|---|---|---|
| | | 5 | 6 | 7 | Example 3 | 8 | 9 |
| Ion cleaning | Vacuum | 3.6 | 3.6 | 3.6 | 3.6 | 3.6 | 3.6 |
| parameter | degree | | | | | | |
| | (×10⁻⁸ Torr) | | | | | | |
| | Ar flow rate | 59 | 59 | 59 | 59 | 59 | 59 |
| | (sccm) | | | | | | |
| | Ion source | 50 | 50 | 50 | 50 | 50 | 50 |
| | power (W) | | | | | | |
| | Working | 10 | 10 | 10 | 10 | 10 | 10 |
| | pressure | | | | | | |
| | (mTorr) | | | | | | |
| | Time (s) | 180 | 180 | 180 | 180 | 180 | 180 |
| Pre-sputtering | Mass flow | 20% | 20% | 20% | 20% | 20% | 20% |
| Parameter | ratio | | | | | | |
| | (N₂:Ar) | | | | | | |
| | Sputtering | 300 | 300 | 300 | 300 | 300 | 300 |
| | power (W) | | | | | | |
| | Deposition | 10 | 10 | 10 | 10 | 10 | 10 |
| | pressure | | | | | | |
| | (mTorr) | | | | | | |
| | Sputtering | 180 | 180 | 180 | 180 | 180 | 180 |
| | time (s) | | | | | | |
| Sputtering | Mass flow | 30% | 40% | 50% | 20% | 20% | 20% |
| Parameter | ratio | | | | | | |
| | (N₂:Ar) | | | | | | |
| | Sputtering | 300 | 300 | 300 | 300 | 300 | 300 |
| | power (W) | | | | | | |
| | Deposition | 3.1 | 3.1 | 3.1 | 2.0 | 5 | 10 |
| | pressure | | | | | | |
| | (mTorr) | | | | | | |
| | Sputtering | 540 | 540 | 540 | 540 | 540 | 540 |
| | time (s) | | | | | | |
| Stress | (MPa) | −262.9 | −293.1 | −393.4 | 908.75 | −64 | −112.7 |
| Thickness | (nm) | 100 | 80 | 73 | 141 | 126 | 120 |

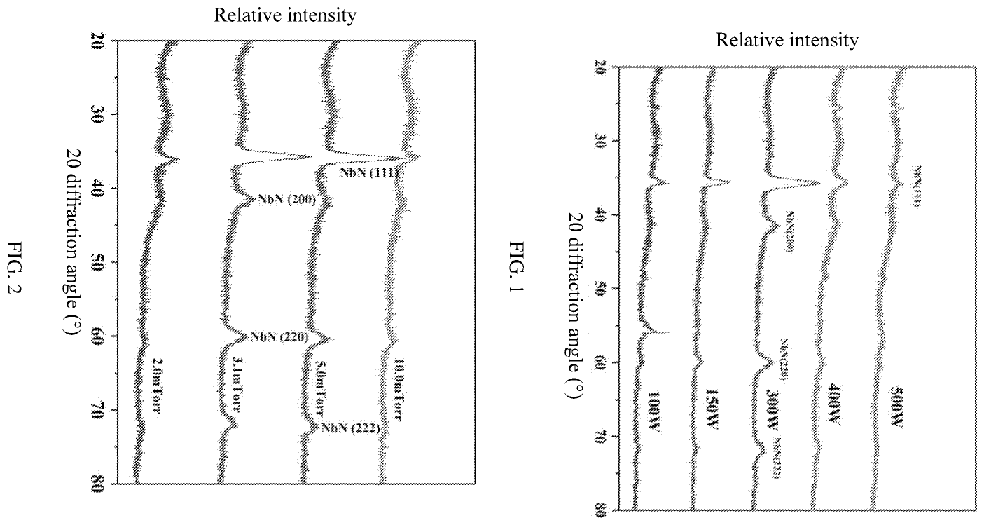

FIG. 1 shows the XRD diffraction patterns of NbN superconducting thin films prepared in Examples 1-4 and Comparative Example 1. Through analysis of the XRD diffraction patterns, it can be seen that with increase of the sputtering power, diffraction peaks of NbN (111), NON (200) and NbN (220) are increased first and then weakened, and XRD diffraction peaks at the sputtering power of 500 W are weak. This is because when the sputtering power is high, the sputtering rate of the thin film increases, and the energy of sputtered atoms reaching the substrate is high. However, many sputtered atoms do not have enough time to move to positions with the lowest energy. During the nucleation and crystallization of the film, it is easy to generate more holes, defects and dislocations, greatly reducing the quality of the film and increasing stress to 968 MPa, exceeding the low stress range. When the sputtering power is 300 W, the diffraction peaks of NbN (111), NbN (200) and NbN (220) are the strongest, indicating that the thin film has the highest crystallization quality with the corresponding stress is 32 MPa, belonging to the low stress range.

FIG. 2 shows the XRD diffraction patterns of NbN superconducting thin films prepared in Examples 3, 5, 6, 7 and Comparative Example 2. Through analysis of the XRD diffraction patterns, it can be seen that with increase of the N₂ flow rate, the diffraction peaks of NbN (111), NbN (200) and NbN (220) are increased first and then weakened, and the XRD diffraction peaks under the N₂/Ar mass flow ratio of 10% and 50% are weak. This is mainly because when less nitrogen is introduced, the reactants are mainly metals and the sputtering mode is dominated by the metal mode. The deposition rate of the thin film is relatively high, which can lead to the formation of many defects, pores, and dislocations during crystal nucleation and growth, ultimately leading to a decrease in the quality of the thin film and the correspondingly stress increases to 939.5 MPa, exceeding the low stress range. When the N₂/Ar mass flow ratio is 20%, the diffraction peaks of NbN (111), NbN (200) and NbN (220) are the strongest, the deposition rate is moderate, and the reactive sputtering mode becomes an ideal compound mode. In this case, the NbN thin film has the highest quality, and the corresponding minimum stress is-214 MPa, which is in the low stress range.

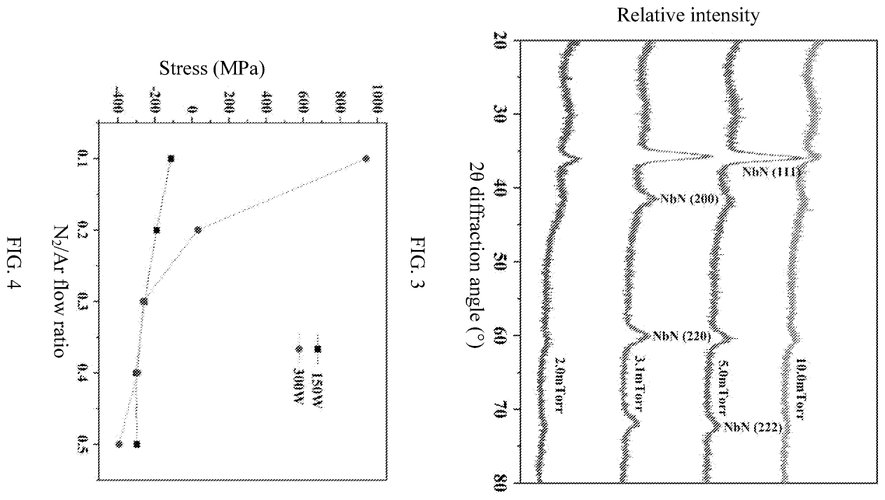

FIG. 3 shows the XRD diffraction patterns of NbN superconducting thin films prepared in Examples 3, 8, 9 and Comparative Example 3. Through analysis of the XRD diffraction patterns, it can be seen that with increase of the deposition pressure, diffraction peaks of NbN (111), NbN (200) and NbN (220) are increased first and then weakened, and the XRD diffraction peaks at the deposition pressure of 2.0 mTorr and 10.0 mTorr are weak. This is mainly because when the deposition pressure is low, the gas has a relatively lower scattering effect, and the deposition rate of the film is high. Therefore, the corresponding stress under 2.0 mTorr is 908.75 MPa, which is not in the low stress range. As the overall pressure increases, the concentration of N₂ molecules in the deposition chamber increases. Meanwhile, the probability of Nb ions colliding with N ions during the process of reaching the substrate surface increases, resulting in a significant loss of kinetic energy and a poor crystallinity of the film. When the sputtering pressure is appropriate, while ensuring the formation of stable glow, the sputtering particles can obtain more suitable kinetic energy under the action of voltage, find suitable lattice positions for film formation, which is conducive to nucleation and crystallization of sputtered atoms reaching the substrate surface, thereby reducing internal defects of the film and improving the crystal crystallization quality of the film.

FIG. 4 shows the variation of the internal stress of NbN superconducting thin film with the N₂/Ar flow ratio under the condition of sputtering power of 300 W and deposition pressure of 3.1 mTorr. Through analysis, it can be seen that based on systematic research on the influence of the sputtering power, the N₂ flow rate and the deposition pressure on crystallization properties of NbN thin film, optimal process parameters, including the sputtering power of 300 W, the N₂/Ar mass flow ratio of 20% and the deposition pressure of 3.1 mTorr, are obtained. During the process of controlling the internal stress of the NbN thin film, two of the parameters will be fixed to investigate the effect of another variable on the internal stress of film, in order to obtain the synergistic effects of—the sputtering power, N₂/Ar mass flow ratio, deposition pressure, and even the deposition rate and thin film thickness on the internal stress of the film. When less nitrogen is introduced, the probability of Nb ions colliding with N ions during the process of reaching the substrate surface is relatively low. The crystal nucleation process is greatly constrained by the substrate, exhibiting tensile stress. At this time, the reactants are mainly metal, and the sputtering mode is dominated by metal mode. The deposition rate of the thin film is relatively high; And there are many defects inside the film, resulting in high internal stress.

When less of nitrogen is introduced, the probability of Nb ions colliding with N ions during the process of reaching substrate surface is relatively low, crystal nucleation process is greatly constrained by the substrate, showing tensile stress. At this time, reactants are mainly metals, and the—sputtering mode is dominated by metal mode. The deposition rate of the—film is relatively high and there are many defects inside the film, resulting in high internal stress. When the N₂ concentration of is appropriate, the deposition rate is moderate, the reactive sputtering mode becomes an ideal compound mode. Sputtered particles can obtain more suitable kinetic energy under the bias, find suitable lattice positions for film crystallization, which is conducive to nucleation and crystallization of sputtered atoms when they reach substrate surface, thereby reducing internal defects in the film, releasing internal stress, and reducing internal stress. When the N₂ concentration of further increased, the collision opportunity between sputtered ions gas molecules increases, resulting in a significant loss of kinetic energy, leading to a decrease in film density and an increase in internal stress in the film.

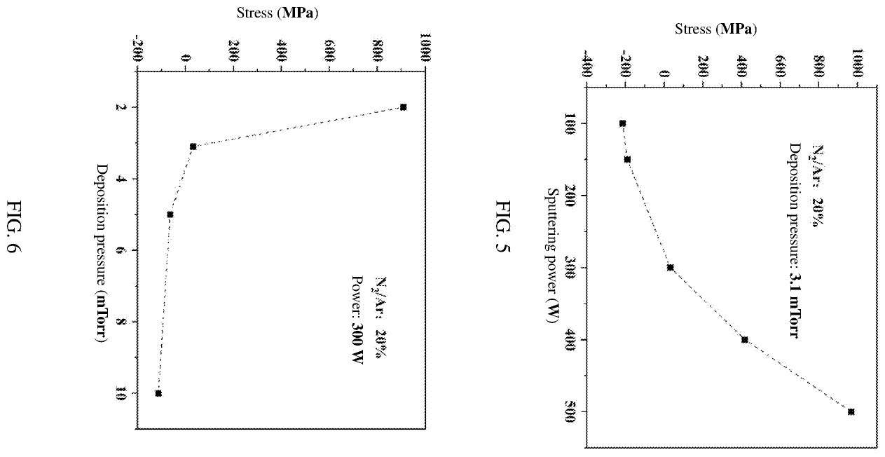

FIG. 5 shows the variation of the internal stress of NbN superconducting thin film with the sputtering power under the conditions of N₂/Ar flow ratio of 20% and the deposition pressure of 3.1 mTorr. As the sputtering power increases, the internal stress of the thin film transitions from compressive stress to tensile stress, with numerical values decreasing first and then increasing. Through analysis, As the sputtering power increases, the internal stress of the thin film is changed from compressive stress to tensile stress, with numerical values decreasing first and then increasing. This is mainly because when the sputtering power is low, the energy of the sputtered atoms is lower, and the sputtering rate is also slow, resulting in a decrease in the effect of the substrate on the thin film This is mainly because when the sputtering power is low, the energy of sputtered atoms is lower, and the sputtering rate is also slow, resulting in a decrease in the effect of the substrate on the thin film. The lattice constant of SiNₓ thin film is about 0.77 nm, while the lattice constant of NbN thin film is 0.43 nm, characterized by compressive stress. As the sputtering power is further increases, the energy of Ar ions and Nb particles becomes stronger, and this energy is sufficient to cause Nb and N atoms to undergo a wide range of lateral migration on the substrate surface, causing the structure of the film to be adjusted during film formation, further releasing internal stress and reducing stress. When the sputtering power further increases, the sputtering rate of the thin film accelerates, and the energy of the sputtered atoms reaching the substrate is high. Within the same time, the thickness of the film increases, resulting in an increase in—the probability of pores, defects and dislocations generated during nucleation and crystallization process of the film. This leads to a further increase in the internal stress of the. The smallest internal stress of NbN films is 32 MPa under the condition of the sputtering power of 300 W.

FIG. 6 shows the variation of the internal stress of NbN superconducting thin film with the deposition pressure under the conditions of N₂/Ar flow ratio of 20% and the sputtering power of 300 W. Through analysis, As the deposition pressure increases, the internal stress of NbN thin film is decreased significantly from 908.75 MPa at a pressure of 2.0 mTorr to 32 MPa at a pressure of 3.1 mTorr. As the deposition pressure increases, the tensile stress becomes compressive stress, and the value slowly increases. This is mainly because when the deposition pressure is low, there are few gas molecules, and the probability of Nb ions colliding with N ions during the process of reaching the substrate surface is low. The crystal nucleation process is greatly constrained by the substrate, resulting in higher internal stress. As the deposition pressure increases, the N₂ concentration increases. At the same time, the probability of Nb ions colliding with N ions during the process of reaching the substrate surface increases, causing the structure of film to be adjusted during film formation, further releasing the internal stress, and reducing stress. As the reaction pressure continues to increase, the density of gas molecules in the vacuum chamber gradually increases. Sputtered ions fly towards the substrate deposition path, resulting in a significant loss of kinetic energy due to increased collision opportunities with gas molecules, leading to a decrease in film density and an increase in internal stress in the film.

The technical schemes and beneficial effects of the present invention have been described in detail through the above specific embodiments. It is to be understood that the above descriptions are merely the most preferred embodiments of the present invention and are not intended to limit the present invention. Any modifications, supplements, equivalent substitutions and the like made within the scope of principles of the present invention shall be included within the scope of protection of the present invention.

1. A preparation method for a low-stress niobium nitride (NbN) superconducting thin film, comprising the following steps:
providing metal Nb targets and Si-based substrates, fixing the Si-based substrate at room temperature, adjusting the mass flow ratio of N₂/Ar to 20%-40%, a sputtering power to 100-300 W, a deposition pressure to 3.0-10.0 mTorr, and NbN superconducting thin films with a stress range of −300 MPa˜300 MPa and a thickness of 70-150 nm are deposited on the Si-based substrates.

2. (canceled)

3. The preparation method for a low-stress NbN superconducting thin film according to claim 1, wherein the mass flow ratio of N₂/Ar is 20%˜25%, the sputtering power is 150˜300 W, the deposition pressure is 3.0˜10.0 mTorr, and NbN superconducting thin films with a stress range of −200 MPa˜200 MPa and a thickness of 70˜150 nm are deposited on the Si-based substrates.

4. The preparation method for a low-stress NbN superconducting thin film according to claim 1, wherein the mass flow ratio of N₂/Ar is 20%-25%, the sputtering power is 200-300 W, the deposition pressure is 3.0-8.0 mTorr, and NbN superconducting thin films with a stress range of −100 MPa˜100 MPa and a thickness of 70˜150 nm are deposited on the Si-based substrates.

5. The preparation method for a low-stress NbN superconducting thin film according to claim 1, wherein the Si-based substrate is a high-resistance Si-substrate coated with SiNₓ thin film.

6. The preparation method for a low-stress NbN superconducting thin film according to claim 1, wherein after the metal Nb target and the Si-based substrate are placed into the deposition chamber, the deposition chamber needs to be vacuumized to an ultrahigh vacuum, where the background vacuum degree is less than 5.0×10⁻⁸ Torr.

7. The preparation method for low-stress NbN superconducting thin film according to claim 1, wherein the Si-based substrate needs to be cleaned before loaded in the film deposition chamber, specifically, the Si-based substrate is subjected to 1-3 min ion cleaning-to remove impurity ions on the substrate surface, the ion beam used for ion cleaning is an argon ion beam, with an ion cleaning vacuum environment of <5.0×10⁻⁸ Torr, an argon gas flow rate of 20-100 sccm, an ion source power of 30-100W, a working pressure of 1.0 mTorr˜10.0 mTorr, and an ion cleaning time controlled between 60 seconds and 300 seconds.

8. The preparation method for a low-stress NbN superconducting thin film according to claim 1, wherein before depositing NbN superconducting thin film on the Si-based substrates, pre-sputtering is also included; the pre-sputtering parameters are: the mass flow ratio of N₂/Ar is 5%-50%, sputtering power of 50-800 W, deposition pressure of 1.0-10.0 mTorr, and the sputtering time of 60-300 seconds.

9. The low-stress NbN superconducting thin film, wherein the low-stress NbN superconducting thin film is prepared by the method in claim 1, with a thickness of 70-150 nm.

10. A method of using a low-stress NbN superconducting thin film in a terahertz superconducting dynamic inductance thermal detector, wherein the low-stress NbN superconducting thin film is prepared by the method according to claim 1, wherein the bending dynamic inductance of the low-stress NbN superconducting thin film is used as a temperature sensor in the terahertz superconducting dynamic inductance thermal detector.
